(19) United States
(12) Patent Application Publication
(10) Pub. No.: US 2009/0321781 A1
(43) Pub. Date: Dec. 31, 2009

(54) QUANTUM DOT DEVICE AND METHOD OF MAKING THE SAME

(76) Inventors: Victoria BROADLEY, Oxon (GB); Katherine Louise Smith, Oxford (GB); Mathieu Xavier Senes, Oxford (GB); Stewart Edward Hooper, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/147,667

(22) Filed: Jun. 27, 2008

(51) Int. Cl. H01L 33/00; H01L 21/00

(52) U.S. Cl. 257/103; 438/47; 257/E33.001; 257/E21.001; 977/762

(57) ABSTRACT

A semiconductor device includes an AlₓGa_{y}In_{1-x-y}N layer and (Al,Ga,In)N quantum dots disposed on the AlₓGa_{y}In_{1-x-y}N layer, wherein the indium fraction in the AlₓGa_{y}In_{1-x-y}N layer is non-zero (1-x-y≠0).

### TECHNICAL FIELD

The present invention relates to a device containing quantum dots and in particular to a device fabricated in the (Al,Ga,In)N material system and also the method of making the same. The invention may be applied to, for example, a semiconductor light emitting diode, a laser diode or a spintronic device.

### BACKGROUND OF THE INVENTION

The characteristics of a semiconductor device are determined by the nature of the active region of the device. In optoelectronic devices, the active region is the source of the optical emission of the device and for a spintronic device the active region controls the properties of the spin. The active region can be formed from bulk layers, which display no quantum size effects, or from quantum wells, quantum wires or quantum dots. The particular application of the semiconductor device depends on the type of active region and also the material system from which the active region is fabricated. The (Al,Ga,In)N material system has generated much interest over the past 10 years due to its application to the UV, blue and visible light regions of the electromagnetic spectrum, rendering it ideal for use in solid state lighting. As a result semiconductor lasers containing InGaN quantum wells have been developed and are now widely available.

Devices containing quantum dot active regions offer many possible advantages over their quantum well counterparts. The confinement of electrons or holes or electrons and holes (hereafter both electrons and holes are referred to as carriers) in three dimensions results in significant quantization effects. Efficient carrier localisation in nitride quantum dot heterostructures has been shown to reduce the effect of the non-radiative processes that occur in devices fabricated in the (Al,Ga,In)N material system, due to the intrinsic high dislocation density present in (Al,Ga,In)N materials, showing a significant improvement over their quantum well counterparts (Y. H. Cho et al., Appl. Phys. Lett. 89 251914 (2006)). Nitride laser diodes containing quantum dots are also predicted to have weaker temperature dependence and lower threshold current characteristics than quantum well laser diodes (Y. Arakawa. IEEE J. Sel. Top. Quantum. Electron. 8, 823 (2002)). Nitride quantum dots have also shown potential for use in spin devices, due to the long spin lifetime (Krishnamurthy et al, APL 83,1761 (2003)).

Epitaxial quantum dots may be formed on a substrate by a variety of means. A commonly used method is self-assembly, whereby the quantum dots are epitaxially grown on a substrate having an in-plane lattice parameter, not matching the in-plane lattice parameter of the quantum dot material. In this way the quantum dot layer is grown under strain and at some critical thickness the layer elastically relaxes to form three-dimensional islands. (The difference between the in-plane lattice parameters of the substrate and the quantum dot material will be hereafter referred to as the lattice mismatch).

The best-known mode for growth of self-organised quantum dots is the Stranski-Krastanov mode (referred to as SK mode hereafter). The growth initially starts with the deposition of a 2D layer of the active material, which is called the wetting layer, on a substrate. As the growth progresses, at some critical thickness, referred to as the critical thickness of the wetting layer, the layer elastically relaxes and forms a 3D surface of islands, known as quantum dots. The quantum dots may then be subjected to a growth interrupt, where no additional material is deposited and whereby further self-organisation of the quantum dots may occur. The quantum dots may then be capped with a layer having a larger bandgap than the quantum dots, therefore forming a quantum box. Subsequent SK growth may be performed on top of the capping layer, if the lattice mismatch is retained and in this way multiple layers of quantum dots may be formed. This growth may be carried out by molecular beam epitaxy or MOVPE.

Quantum dots formed from a material having a larger lattice parameter than that of the substrate have compressive strain. Quantum dots formed from a material having a smaller lattice parameter than that of the substrate are tensile strained.

The lattice mismatch plays a significant role in determining the size, shape and density of the quantum dots. In this way the properties of the dots can be controlled through the manipulation of the substrate material and its lattice parameter.

The growth of nitride quantum dots using the SK mode of self-organised growth is well reported in the literature. The properties of the quantum dots depend largely on the starting substrate and also the growth conditions. C.-H. Shen at al., Thin Solid Films 494, 79-83 (2006) describe the SK growth of InN quantum dots on AlN and GaN substrates by plasma assisted MBE. They observed that the lattice parameter of the growth varied dramatically at the 2D-3D transition point, such that the resulting InN quantum dots were completely relaxed. However, they did not manipulate the strain at the surface of the AlN or GaN substrates.

B. Daudin et al., Phys. Rev. B. 56 R7069 (1997) describe the SK growth of GaN quantum dots on an AlN substrate, where the size and distribution of the GaN quantum dots are controlled by varying the growth temperature.

The properties of the starting substrate can also be used to control the growth of SK mode quantum dots. Y. Hori et al., J. Appl. Phys. 102, 024311 (2007) demonstrate control of the growth of GaN dots on strained AlₓGa₁₋ₓN on AlN substrates, through the manipulation of the aluminium content, x and the thickness of the AlₓGa₁₋ₓN layer. By varying the thickness of the AlₓGa₁₋ₓN layer below the critical thickness, defined as the thickness of a layer at which it plastically relaxes to its native lattice constant, they are able to provide a substrate for SK growth with varying built in strain. By monitoring the in-plane lattice parameter and therefore the strain in the quantum dots during the growth using Reflection High Energy Electron Diffraction (RHEED) they observe that the quantum dot growth is affected by not only the lattice mismatch with the substrate but also the chemical composition of the substrate. FIG. 1 shows the variation in the quantum dot properties with increasing aluminium fraction for 0.2≦x≦1.0, in the prior art. FIG. 2 shows the difference in in-plane lattice parameter between the quantum dots and the AlₓGa₁₋ₓN substrate (lattice mismatch) with increasing aluminium content for AlₓGa₁₋ₓN layers with different thicknesses, in the prior art. The authors propose that the interfacial energy due to the chemical differences between GaN and AlN influences the GaN quantum dot growth. They find that for substrates with high Al content the elastic energy due to the lattice mismatch dominates the SK growth, whereas for low Al content the interfacial energy between GaN and AlN dominates the growth. The manipulation of GaN quantum dots on AlₓGa₁₋ₓN substrates allows the growth of compressively strained quantum dots. However, the stacking of multiple layers of quantum dots grown in this way will lead to the overall build up of strain in the device.

U.S. Pat. No. 6,992,320 describes a method to grow quantum dots under tensile strain, in particular for (In,Ga,N)As dots grown on InP. In this situation the lattice parameter of the quantum dot material is smaller than the lattice parameter of the substrate. However, a multiple quantum dot layered device grown using either the method of U.S. Pat. No. 6,992,320 or Y. Hori et al. would be highly strained.

The build up of strain in a nitride device is shown to have a detrimental effect on the properties of the device. FIG. 3 shows the output power from an InGaN quantum dot LED for increasing number of stacked quantum dot layers. The output power increases linearly with increasing number of layers up to five layers and thereafter decreases suddenly for any additional layers. This degradation in performance for devices with more than five stacked layers of quantum dots is attributed to the build up of strain in the device and its effect on the quantum dot growth. FIG. 4 shows a photoluminescence spectrum of a LED containing seven layers of InGaN quantum dots. The spectrum is fitted by two separate Gaussians indicating the presence of two families of quantum dots with different properties. In order to achieve high power optoelectronic devices containing InGaN quantum dots, suitable for use in solid-state lighting, active regions containing high numbers of stacked quantum dot layers are required. Therefore a method that enables the growth of multiple quantum dot layers without the build up of strain is required.

### SUMMARY OF THE INVENTION

According to an aspect of the present invention, a semiconductor device is provided which includes an AlₓGa_{y}In_{1-x-y}N layer and (Al,Ga,In)N quantum dots disposed on the AlₓGa_{y}In_{1-x-y}N layer, wherein the indium fraction in the AlₓGa_{y}In_{1-x-y}N layer is non-zero (1-x-y≠0).

In an embodiment, the AlₓGa_{y}In_{1-x-y}N layer has a composition in which 0≦x≦1.0.

According to another embodiment, the AlₓGa_{y}In_{1-x-y}N layer has a composition in which 0≦x≦0.6.

In yet another embodiment, the AlₓGa_{y}In_{1-x-y}N layer has a composition in which y=0.

In still another embodiment, the composition of the (Al,Ga,In)N quantum dots is AlₓGa_{y}In_{1-x-y}N.

According to another embodiment, 0≦x≦1.0 and 0≦y≦1.0 with respect to the composition of the quantum dots.

According to still another embodiment, 0.7≦x≦0.95 with respect to the composition of the quantum dots.

In another embodiment, y=0 with respect to the composition of the quantum dots.

In still another embodiment, the semiconductor device includes a barrier layer formed on the quantum dots.

In accordance with another embodiment, the AlₓGa_{y}In_{1-x-y}N layer, the quantum dots disposed on the AlₓGa_{y}In_{1-x-y}N layer, and the barrier layer, if included, are repeated to form a stacked device.

With still another embodiment, a thickness and composition of the AlₓGa_{y}In_{1-x-y}N layer, the quantum dots and the barrier layer, if included, are such that the overall strain in the device is balanced to substantially zero.

According to another embodiment, the semiconductor device further includes a capping layer having a composition of AlₓGa₁₋ₓN.

In another embodiment, x=0 with respect to the composition of the capping layer.

In yet another embodiment, the semiconductor device further includes a strain balancing layer having a composition of AlₓGa_{y}In_{1-x-y}N where the indium fraction of the strain balancing layer is non-zero (1-x-y≠0).

According to another aspect of the invention, a method of making a semiconductor device is provided. The method includes forming an AlₓGa_{y}In_{1-x-y}N layer and forming (Al,Ga,In)N quantum dots on the AlₓGa_{y}In_{1-x-y}N layer, wherein the indium fraction in the AlₓGa_{y}In_{1-x-y}N layer is non-zero (1-x-y≠0).

In an embodiment, the method includes controlling the thickness and composition of the AlₓGa_{y}In_{1-x-y}N layer and the quantum dots such that the overall strain in the device is balanced to substantially zero.

In another embodiment, the method includes growing the AlₓGa_{y}In_{1-x-y}N layer under compressive strain, and where 0≦x≦0.83 and y=0.

According to another embodiment, the method incudes growing the AlₓGa_{y}In_{1-x-y}N layer under tensile strain, and where 0.83≦x≦1.0 and y=0.

According to still another embodiment, the steps of forming an AlₓGa_{y}In_{1-x-y}N layer and forming (Al,Ga,In)N quantum dots on the AlₓGa_{y}In_{1-x-y}N layer are repeated to form a stacked device.

In yet another embodiment, the method includes using the multiple AlₓGa_{y}In_{1-x-y}N layers as strain balancing layers within the stacked device having multiple quantum layers.

According to another embodiment, the quantum dots have a composition of AlₓGa_{y}In_{1-x-y}N.

In still another embodiment, the method includes forming a barrier layer on the quantum dots.

In another embodiment, the barrier layer is composed of GaN.

According to another embodiment, the method includes forming a capping layer having a composition of AlₓGa₁₋ₓN.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1. is a graph showing the height, diameter and density of GaN quantum dots grown on AlₓGa₁₋ₓ N substrates in the prior art for different aluminium concentrations.

FIG. 2. is a graph of change in the relative variation of in-plane lattice parameter as a function of aluminium content for GaN quantum dots on AlₓGa₁₋ₓ N layers of varying thickness in the prior art.

FIG. 3. is a graph of quantum dot LED power against number of quantum dot layers.

FIG. 4. is a photoluminescence graph for an LED containing seven layers of quantum dots, showing the double Gaussian fit.

FIG. 5. is a graph showing the in-plane lattice parameter against band-gap for compounds in the (Al,Ga,In)N material system

FIG. 6. is a schematic of a layer of InGaN quantum dots disposed on an AlₓGa_{y}In_{1-x-y}N layer and capped with an AlₓGa₁₋ₓ N barrier layer, according to an embodiment of the present invention.

FIG. 7. is a schematic of a multiple layers of InGaN quantum dots disposed on AlₓGa_{y}In_{1-x-y}N layers and capped with AlₓGa₁₋ₓN barrier layers according to an embodiment of the present invention.

FIG. 8. is a schematic of a multiple layers of InGaN quantum dots disposed on AlₓGa_{y}In_{1-x-y}N layers according to an embodiment of the present invention.

FIG. 9. is a schematic of a light emitting device containing InGaN quantum dots disposed on an AlₓGa_{y}In_{1-x-y}N layers within the active region of the device, according to an embodiment of the present invention.

FIG. 10. is a schematic of a light emitting diode device containing multiple layers of InGaN quantum dots disposed on AlₓGa_{y}In_{1-x-y}N layers with an additional AlₓGa_{y}In_{1-x-y}N strain balancing layer on top of the active region of the device, according to an embodiment of the present invention.

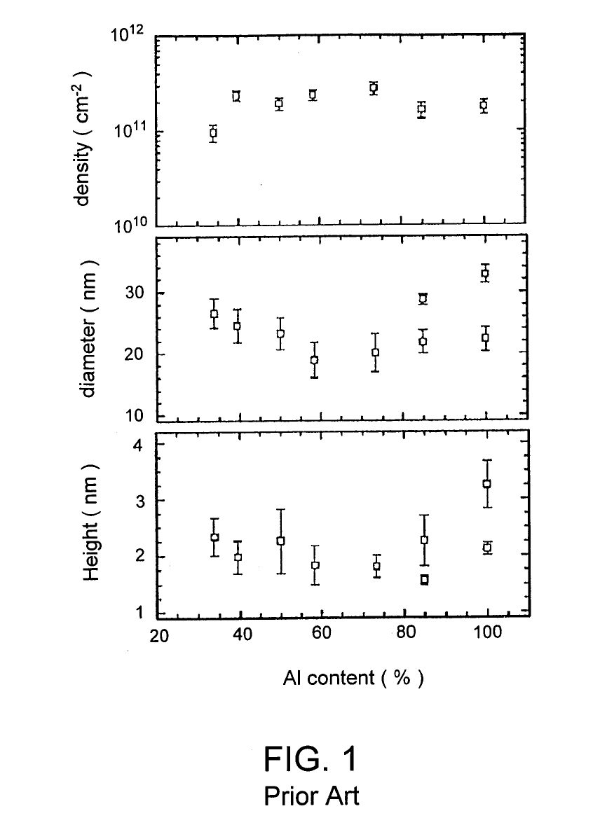

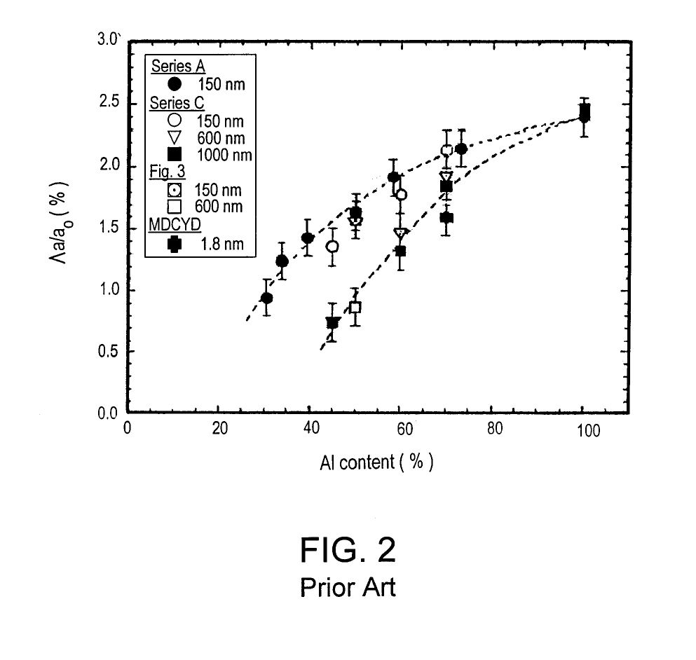

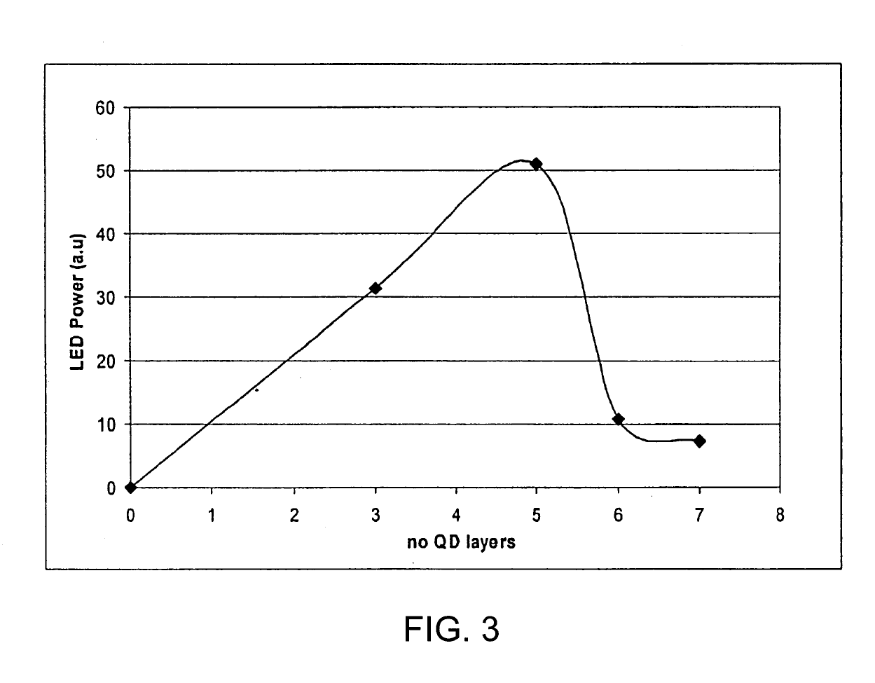

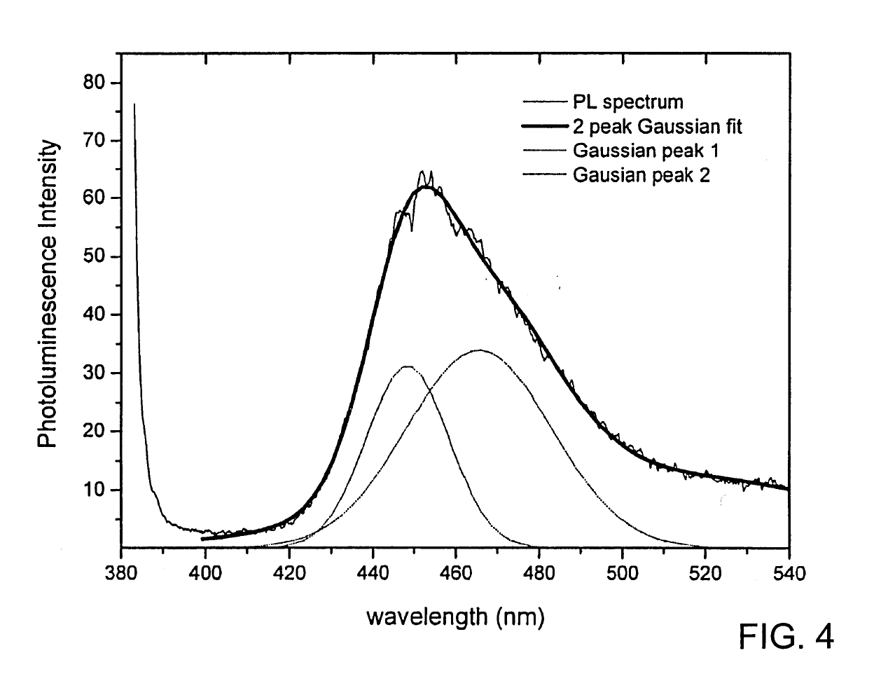

### DETAILED DESCRIPTION OF THE INVENTION

The present invention will be described with reference to the drawings, wherein like reference labels are utilized to refer to like elements.

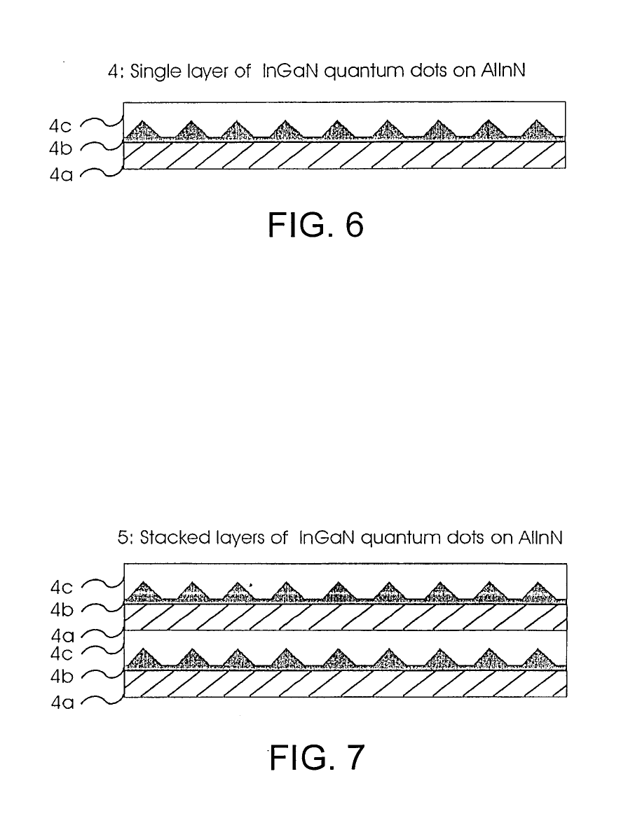

Referring to FIGS. 6 and 7, the present invention comprises a semiconductor device containing (Al,Ga,In)N quantum dots 4b disposed on an AlₓGa_{y}In_{1-x-y}N layer 4a. The present invention provides a semiconductor device containing single or multiple (Al,Ga,In)N quantum dot layers 4b where the strain in the total device can be balanced. The invention provides a method of controlling the growth of the (Al,Ga,In)N quantum dots through the manipulation of the lattice parameter of the underlying AlₓGa_{y}In_{1-x-y}N layer. The thickness and composition of of the AlₓGa_{y}In_{1-x-y}N layer(s) may be tailored across the whole compositional range for 0≦x≦1.0 wherein the In fraction is non-zero (1-x-y)≠0 (as shown in FIG. 6) such that the growth of the (Al,Ga,In)N quantum dots layer(s) may be controlled to achieve a required quantum dot size, shape or distribution whilst also allowing the overall strain in the device to be balanced to zero.

The (Al,Ga,In)N quantum dots may be grown using the SK growth mode by either MBE or MOCVD, for example. The AlₓGa_{y}In_{1-x-y}N layer 4a may have a thickness between 1 nm and 200 nm. The quantum dots may have a height less than 50 nm. The quantum dots may have a height between 1 nm and 5 nm. An AlₓGa₁₋ₓN barrier layer 4c is disposed on top of the quantum dots 4b, wherein the bandgap of the barrier layer 4c is greater than the bandgap of the quantum dots 4b. The thickness of the barrier layer 4c may be between 1 nm and 50 nm. A subsequent AlₓGa_{y}In_{1-x-y}N layer 4a may be disposed on top of the AlₓGa₁₋ₓN barrier layer 4c. Further quantum dot layers 4b may be grown on top of the layer 4a. In this way a device comprising a stack of (Al,Ga,In)N quantum dots layers grown on AlₓGa_{y}In_{1-x-y}N may be grown. All the AlₓGa_{y}In_{1-x-y}N layers in the stack may be identical. The thickness and composition of the AlₓGa_{y}In_{1-x-y}N layer may vary for subsequent layers in the stack. The size, composition, density of the quantum dots may be identical for all the quantum dot layers in the stack. The size, composition, density of the quantum dots may vary for subsequent layers in the stack. The AlₓGa_{y}In_{1-x-y}N layer may be disposed on a GaN substrate such that the thickness of the AlₓGa_{y}In_{1-x-y}N layer is less than the critical thickness of said layer and the layer is grown strained to the GaN substrate. Thus an AlₓGa_{y}In_{1-x-y}N layer grown in this way with aluminium content 0≦x≦0.83 and y=0 is grown under compressive strain. Alternatively an AlₓGa_{y}In_{1-x-y}N layer grown with aluminium content 0.83≦x≦1.0 and y=0 is grown with tensile strain. The growth of both tensile strained and compressively strained AlₓGa_{y}In_{1-x-y}N layers in a quantum dot device provides the possibility to strain balance the device.

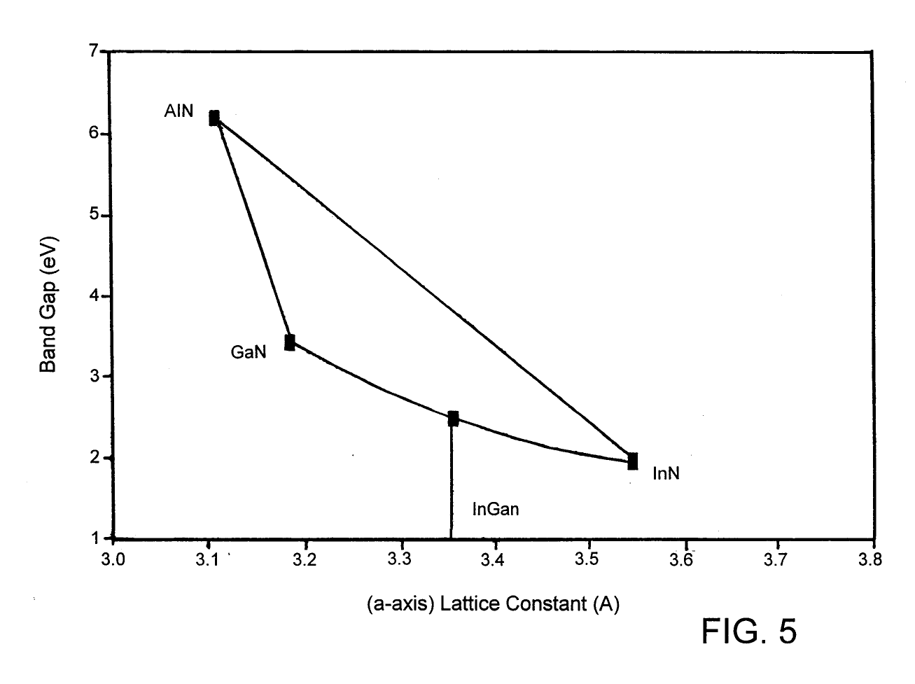

The present invention provides a device containing (Al,In,Ga)N quantum dots disposed on an AlₓGa_{y}In_{1-x-y}N layer, where the properties of the (Al,In,Ga)N quantum dots may be controlled by varying the thickness and aluminium fraction of the AlₓGa_{y}In_{1-x-y}N layer whilst at the same time enabling the AlₓGa_{y}In_{1-x-y}N layer to act as a strain-balancing layer in a multiple quantum dot layer device. The lattice parameter of AlₓGa_{y}In_{1-x-y}N layer maybe varied across a much wider range of values than any other compound in the (Al,Ga,In)N material system, as shown in FIG. 5 (Gallium Nitride (GaN) I Semiconductors and Semimetals Vol. Gallium Nitride (GaN) I, 50, Ed. J. Pankove, T. Moustakas. p 148, 1998), allowing a much greater degree of control over the subsequent growth of quantum dots on top of this layer than for any other substrate material from said material system. Unlike any other compound from the (Al,Ga,In)N material system, AlₓGa_{y}In_{1-x-y}N may be grown under either compressive or tensile strain on a GaN substrate, enabling multiple AlₓGa_{y}In_{1-x-y}N layers to be used as a strain balancing layers in a multi quantum dot layer structure.

The combination of (Al,In,Ga)N quantum dots grown on AlₓGa_{y}In_{1-x-y}N layers provides the opportunity for the production of high power optoelectronic devices with emission wavelengths covering the full visible spectrum, which are ideally suited to solid-state lighting applications.

A device of the present invention may be grown by any suitable means and on any suitable substrate, which includes but is not limited to any orientation of: sapphire, GaN or SiC.

A first embodiment of the present invention is described with reference to FIGS. 6 to 9. According to the first embodiment of this invention FIG. 9 shows a schematic of a light-emitting device 8 fabricated in the (Al,In,Ga)N material system. The light-emitting diode 8 of FIG. 9 comprises a sapphire substrate 1. A buffer layer 2 may be disposed on top of the substrate 1 and the buffer layer may be any compound in the (Al,Ga)N material system. The buffer layer 2 may be not intentionally doped, p-type or n-type in nature. In the light-emitting diode of FIG. 9 the buffer layer is n-type GaN. An n-type (Al,Ga,In)N layer 3 may be disposed on top of the buffer layer 2.

The light emitting diode 8 of FIG. 9 may contain an active region 4 shown also in FIG. 6. The active region may comprise AlₓGa_{y}In_{1-x-y}N quantum dots 4b disposed on an AlₓGa_{y}In_{1-x-y}N layer 4a. The AlₓGa_{y}In_{1-x-y}N layer 4a may have the composition wherein 0≦x≦1. The AlₓGa_{y}In_{1-x-y}N layer 4a has the composition wherein the indium fraction is non-zero such that 1-x-y≠0. The AlₓGa_{y}In_{1-x-y}N layer 4a may preferably have the composition wherein 0≦x≦0.6 and y=0. The AlₓGa_{y}In_{1-x-y}N layer 4a may be grown under compressive strain. The AlₓGa_{y}In_{1-x-y}N layer 4a may be grown under tensile strain. The layer 4a may have a thickness between 1 nm and 200 nm. The layer 4a may have a thickness between 1 nm and 50 nm. The layer 4a may preferably have a thickness less than 10 nm. The layer 4a may be not intentionally doped or alternatively p-type doped or n-type doped. The layer 4a may be preferably not intentionally doped.

The AlₓGa_{y}In_{1-x-y}N quantum dots 4b may have the composition wherein 0≦x≦1.0 and 0≦y≦1.0, such that they may be comprised from GaN, InN, InGaN AlGaN and AlGaInN. The quantum dots 4b may preferably have the composition wherein y=0 and 0.7≦x≦0.95. The quantum dots 4b may have the size wherein all three dimensions are each less than 50 nm. The quantum dots may have a size wherein the height is less than 12 nm. The quantum dots 4b may preferably have a height between 1 nm and 5 nm. The quantum dots 4b may be not intentionally doped or alternatively they may be p-type doped or n-type doped. In this embodiment of the invention the quantum dots 4b are preferably not intentionally doped. An AlₓGa₁₋ₓN barrier layer 4c may be disposed immediately after the AlₓGa_{y}In_{1-x-y}N quantum dots 4b. (The barrier layer 4c may be grown immediately after the quantum dots 4b or alternatively there may be a growth interrupt. The growth interrupt may be between one minute and five minutes.) The AlₓGa₁₋ₓN barrier layer 4c may have the composition wherein 0≦x≦1.0. The barrier layer 4c may have a bandgap that is larger than the band gap of the quantum dots 4b. Preferably the barrier layer 4c has the composition wherein x=0, such that the layer is composed of GaN.

The layer 4c may have a thickness between 1 nm and 100 nm. Preferably the layer 4c may have a thickness less than 10 nm. The layer 4c may be not intentionally doped or may be p-type doped or n-type doped. In this embodiment the layer is preferably not intentionally doped. In this embodiment the thickness and compositions of layers 4a and 4c are such that the overall strain in device 8 is balanced to zero.

According to this embodiment of the present invention the light emitting diode 8, may contain multiple quantum dots layers such that layers 4a, 4b and 4c are repeated to form a stack, 5 as shown in FIG. 7. The active region stack, 5 may be repeated between 1 and 200 times in the device. The region 5 may preferably be repeated between 3 and 20 times. The AlₓGa_{y}In_{1-x-y}N layer 4a in each layer of the stack may be identical. The AlₓGa_{y}In_{1-x-y}N layer 4a in each layer of the stack may vary in composition. The AlₓGa_{y}In_{1-x-y}N layer 4a in each layer of the stack may vary in thickness. In this embodiment of the invention the AlₓGa_{y}In_{1-x-y}N layers in each layer of the stack will have the same thickness and composition. The quantum dots 4b in each layer of the stack 5 may be identical. The quantum dots 4b in each layer of the stack 5 may vary in composition. The quantum dots 4b in each layer of the stack 5 may vary in size. The quantum dots 4b in each layer of the stack 5 may vary in density. In this embodiment the quantum dots 4b in each layer will preferably have the same size, density and composition. In this embodiment the thickness and composition of layers 4a and 4b is such that the overall strain in the structure 5 is balanced to zero.

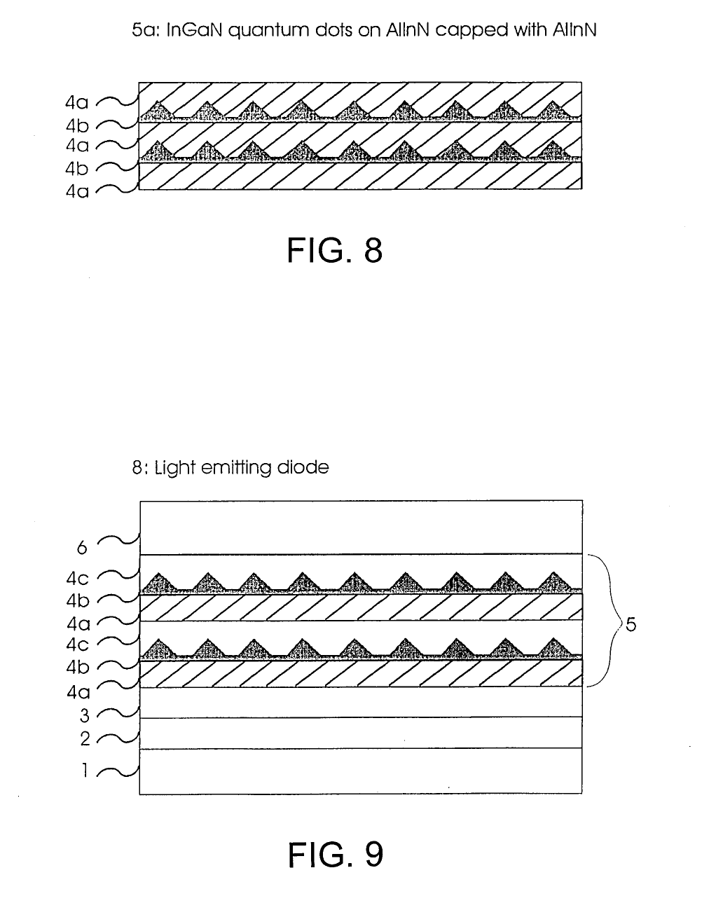

Alternatively the AlₓGa₁₋ₓN barrier layers 4c may be omitted such that the AlₓGa_{y}In_{1-x-y}N layers 4a are in direct contact with the quantum dot layers 4b, below it, as shown for the active region stack 5a in FIG. 8.

An AlₓGa₁₋ₓN capping layer 6 may be disposed on top of the active stack 5. The AlₓGa₁₋ₓN capping layer 6 may have the composition wherein 0≦x≦1.0. The capping layer 6 may preferably have the composition such that x=0. The capping layer 6 may be not intentionally doped or alternatively n-type or p-type doped. Preferably the capping layer 6 will be p-type doped. The capping layer 6 may have a thickness between 1 nm and 1 um. The capping layer may have a thickness less than 100 nm. Preferably the capping layer 6 may have a thickness less than 30 nm.

The final barrier layer 4c in the active regions stack 5 may be omitted, such that the final quantum dot layer 4b is in direct contact with the capping layer 6.

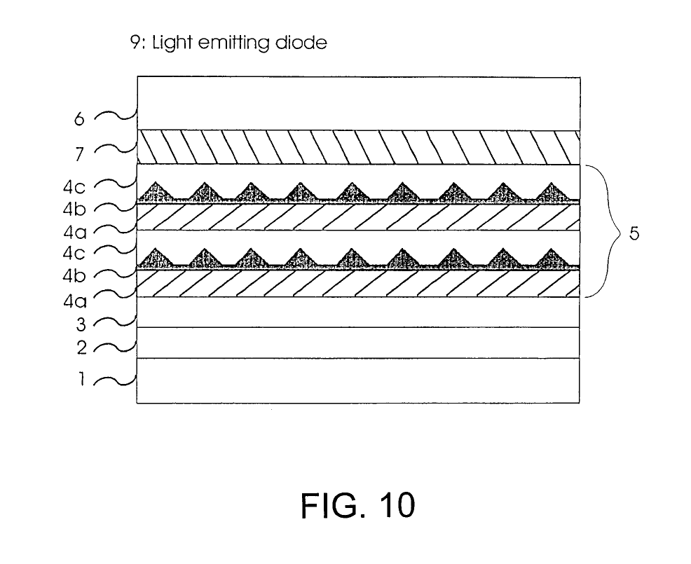

In FIG. 10 a second embodiment of the present invention, a light emitting diode 9, is presented. The layers 1, 2, 3 and 6 are as described in the above-described first embodiment. In this embodiment an additional strain balancing AlₓGa_{y}In_{1-x-y}N layer 7 is disposed on top of the active region stack 5. Layer 7 may be positioned any where in the device 9. Layer 7 may have the composition wherein 0≦x≦1.0. Layer 7 has the composition wherein the indium fraction is non-zero such that (1-x-y)≠0. The layer 7 may preferably have a composition wherein 0≦x≦0.6 and y=0. Layer 7 may have a thickness between 1 and 200 nm. The layer 7 may have a thickness between 1 nm and 50 nm. The layer 7 may preferably have a thickness less than 10 nm. The layer 7 may be not intentionally doped or alternatively p-type doped or n-type doped. The layer 4a may be preferably not intentionally doped. The function of the AlₓGa_{y}In_{1-x-y}N layer 7 is to balance the strain of the entire light emitting diode 9. In this embodiment layer 7 is preferably disposed on top of the final layer 4c in the active region stack 5. The layers 4b and 4c are as described in the first embodiment. The AlₓGa_{y}In_{1-x-y}N layers 4a in the active region stack have a thickness between 0 and 10 nm and compositions 0≦x≦1.0 such that overall strain in the active region stack 5 of device 9 is non-zero. Layer 7 has a thickness and composition such that the overall strain in the full light-emitting device 9 is balanced to zero.

The invention has been described with reference to embodiments of light-emitting diodes. However, the present invention of a device containing AlₓGa_{y}In_{1-x-y}N quantum dots disposed on AlₓGa_{y}In_{1-x-y}N layers is not limited to these devices. The present invention may be extended to any device containing such an active region. This includes but is not limited to laser diodes, spin light-emitting diodes, solar cells, VCSELs, memory devices, transistors, quantum dot transistors, and spintronic devices.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. A semiconductor device, comprising:
an AlₓGa_{y}In_{1-x-y}N layer; and
(Al,Ga,In)N quantum dots disposed on the AlₓGa_{y}In_{1-x-y}N layer,
wherein the indium fraction in the AlₓGa_{y}In_{1-x-y}N layer is non-zero (1-x-y≠0).

2. The semiconductor device of claim 1, wherein the AlₓGa_{y}In_{1-x-y}N layer has a composition in which 0≦x≦1.0.

3. The semiconductor device of claim 1, wherein the AlₓGa_{y}In_{1-x-y}N layer has a composition in which 0≦x≦0.6.

4. The semiconductor device of claim 1, wherein the AlₓGa_{y}In_{1-x-y}N layer has a composition in which y=0.

5. The semiconductor device of claim 1, wherein the composition of the (Al,Ga,In)N quantum dots is AlₓGa_{y}In_{1-x-y}N.

6. The semiconductor device of claim 5, wherein 0≦x≦1.0 and 0≦y≦1.0 with respect to the composition of the quantum dots.

7. The semiconductor device of claim 5, wherein 0.7≦x≦0.95 with respect to the composition of the quantum dots.

8. The semiconductor device of claim 5, wherein y=0 with respect to the composition of the quantum dots.

9. The semiconductor device of claim 1, further comprising a barrier layer formed on the quantum dots.

10. The semiconductor device of claim 1, wherein the AlₓGa_{y}In_{1-x-y}N layer, the quantum dots disposed on the AlₓGa_{y}In_{1-x-y}N layer, and the barrier layer, if included, are repeated to form a stacked device.

11. The semiconductor device of claim 1, wherein a thickness and composition of the AlₓGa_{y}In_{1-x-y}N layer, the quantum dots and the barrier layer, if included, are such that the overall strain in the device is balanced to substantially zero.

12. The semiconductor device of claim 1, further comprising a capping layer having a composition of AlₓGa₁₋ₓN.

13. The semiconductor device of claim 12, wherein x=0 with respect to the composition of the capping layer.

14. The semiconductor device of claim 1, further comprising a strain balancing layer having a composition of AlₓGa_{y}In_{1-x-y}N where the indium fraction of the strain balancing layer is non-zero (1-x-y≠0).

15. A method of making a semiconductor device, comprising:
forming an AlₓGa_{y}In_{1-x-y}N layer; and
forming (Al,Ga,In)N quantum dots on the AlₓGa_{y}In_{1-x-y}N layer,
wherein the indium fraction in the AlₓGa_{y}In_{1-x-y}N layer is non-zero (1-x-y≠0).

16. The method of claim 15, comprising controlling the thickness and composition of the AlₓGa_{y}In_{1-x-y}N layer and the quantum dots such that the overall strain in the device is balanced to substantially zero.

17. The method of claim 15, comprising growing the AlₓGa_{y}In_{1-x-y}N layer under compressive strain, and where 0≦x≦0.83 and y=0.

18. The method of claim 15, comprising growing the AlₓGa_{y}In_{1-x-y}N layer under tensile strain, and where 0.83≦x≦1.0 and y=0.

19. The method of claim 15, wherein the steps of forming an AlₓGa_{y}In_{1-x-y}N layer and forming (Al,Ga,In)N quantum dots on the AlₓGa_{y}In_{1-x-y}N layer are repeated to form a stacked device.

20. The method of claim 19, comprising using the multiple AlₓGa_{y}In_{1-x-y}N layers as strain balancing layers within the stacked device having multiple quantum layers.

21. The method of claim 15, wherein the quantum dots have a composition of AlₓGa_{y}In_{1-x-y}N.

22. The method of claim 15, comprising forming a barrier layer on the quantum dots.

23. The method of claim 22, wherein the barrier layer is composed of GaN.

24. The method of claim 15, comprising forming a capping layer having a composition of AlₓGa₁₋ₓN.
